(19) United States
(12) Patent Application Publication
(10) Pub. No.: US 2025/0212401 A1
(43) Pub. Date: Jun. 26, 2025

(54) SEMICONDUCTOR MEMORY DEVICE AND METHOD FOR FORMING THE SAME

(71) Applicant: Winbond Electronics Corp., Taichung City (TW)

(72) Inventor: Chung-Hsien LIU, Taichung City (TW)

(21) Appl. No.: 18/629,067

(22) Filed: Apr. 8, 2024

(30) Foreign Application Priority Data
Dec. 26, 2023 (TW) 112150801

(51) Int. Cl. H10B 41/30; H01L 21/28; H01L 29/423; H01L 29/66; H01L 29/788

(52) U.S. Cl. CPC H10B 41/30; H10D 30/0411; H10D 30/683; H10D 30/689; H10D 30/6893; H10D 64/035

(57) ABSTRACT

A semiconductor memory device is provided. The semiconductor memory device includes a semiconductor substrate and transistor structures. The transistor structures are disposed on the semiconductor substrate. Each of the transistor structures includes a semiconductor layer, a floating gate, a control gate, a tunneling oxide layer, and an inter-gate dielectric layer. The semiconductor substrate and the semiconductor layer have the same conductivity type and different doping concentrations. The floating gate covers a sidewall of the semiconductor layer and has a curved sidewall opposite the sidewall of the semiconductor layer. The tunneling oxide layer is between the floating gate and the semiconductor substrate and between the first floating gate and the semiconductor layer. A control gate is disposed on the floating gate and an inter-gate dielectric layer is between the control gate and the floating gate and conformally covers the curved sidewall of the first floating gate.

### CROSS REFERENCE TO RELATED APPLICATIONS

This application claims priority of Taiwan Patent Application No. 112150801 filed on Dec. 26, 2023, and entitled “SEMICONDUCTOR MEMORY DEVICE AND METHOD FOR FORMING THE SAME”, the entirety of which is incorporated by reference herein.

### BACKGROUND OF THE INVENTION

### Field of the Invention

The invention relates to a semiconductor structure, and in particular to a semiconductor memory device that can increase the coupling rate between a control gate and a floating gate and a method of forming the same.

### Description of the Related Art

In conventional flash memory devices, the source/drain regions are located on the same plane as the channel region. Changes in device size would directly affect the channel length, thus limiting any reduction in device size. Furthermore, flash memory devices usually use a single channel region for write and erase operations, resulting in a reduction of the endurance of the tunnel oxide layer above the channel region (i.e., reducing the number of write and erase operations) due to multiple writes/erases, so that the reliability of the device is reduced. In addition, when the size of the device is reduced, the capacitance between the floating gate and the control gate stacked on it is also reduced, resulting in a decrease in the coupling ratio between the floating gate and the control gate, so that the operating voltage of the flash memory device (e.g., the voltage applied to the control gate) increases.

### BRIEF SUMMARY OF THE INVENTION

Embodiments of the present disclosure provide a semiconductor memory device and a manufacturing method thereof, which can prevent electrical short circuits caused by the bridging of adjacent storage capacitor contacts during the manufacturing process.

In some embodiments, a semiconductor memory device is provided. The semiconductor memory device includes a semiconductor substrate and a plurality of transistor structures. The semiconductor substrate has a first doping concentration with a first conductivity type. The transistor structures are disposed on the semiconductor substrate, and each of the transistor structures includes a semiconductor layer, a first floating gate, a first control gate, a first tunnel oxide layer, and an inter-gate dielectric layer. The semiconductor layer has a second doping concentration with the first conductivity type. The second doping concentration is different than the first doping concentration. The first floating gate covers a first sidewall of the semiconductor layer and has a curved sidewall opposite to the first sidewall. The first tunnel oxide layer is formed between the first floating gate and the semiconductor substrate, and between the first floating gate and the semiconductor layer. The first control gate is disposed on the first floating gate, and the inter-gate dielectric layer is formed between the first control gate and the first floating gate, and conformally covers the curved sidewall of the first floating gate.

In some embodiments, a method for forming a semiconductor memory device is provided. The method includes forming at least one semiconductor layer on a semiconductor substrate. The semiconductor substrate has a first P-type doping concentration. The semiconductor layer has a second P-type doping concentration. The second P-type doping concentration is different than the first P-type doping concentration. The method also includes conformally forming a first dielectric layer to cover the upper surface of the semiconductor substrate and the upper surface, a first sidewall and an opposing second sidewall of the semiconductor layer, and forming a first floating gate and a second floating gate on the first dielectric layer and to cover the first sidewall and the second sidewall, respectively. The first floating gate and the second floating gate each have a curved sidewall. The curved sidewalls are respectively opposite to the first sidewall and the second sidewall. The method further includes conformally forming a second dielectric layer to cover the upper surface of the semiconductor substrate, the upper surface of the semiconductor layer, the curved sidewall of the first floating gate and the curved sidewall of the second floating gate. Furthermore, the method also includes forming a first control gate and a second control gate that cover the second dielectric layer on the first floating gate and the second floating gate, respectively.

### BRIEF DESCRIPTION OF THE DRAWINGS

FIG. 1 is a cross-sectional view of a semiconductor memory device in accordance with some embodiments.

FIGS. 2A to 2J are cross-sectional views of semiconductor memory devices at various stages of processing in accordance with some embodiments.

### DETAILED DESCRIPTION OF THE INVENTION

The making and using of the embodiments of the present disclosure are discussed in detail below. However, it should be noted that the embodiments provide many applicable inventive concepts that can be embodied in a variety of specific methods. The specific embodiments discussed are merely illustrative of specific methods to make and use the embodiments, and do not limit the scope of the disclosure. In addition, the present disclosure may repeat reference numbers and/or letters in the various embodiments. This repetition is for the purpose of simplicity and clarity, and does not imply any relationship between the different embodiments and/or configurations discussed.

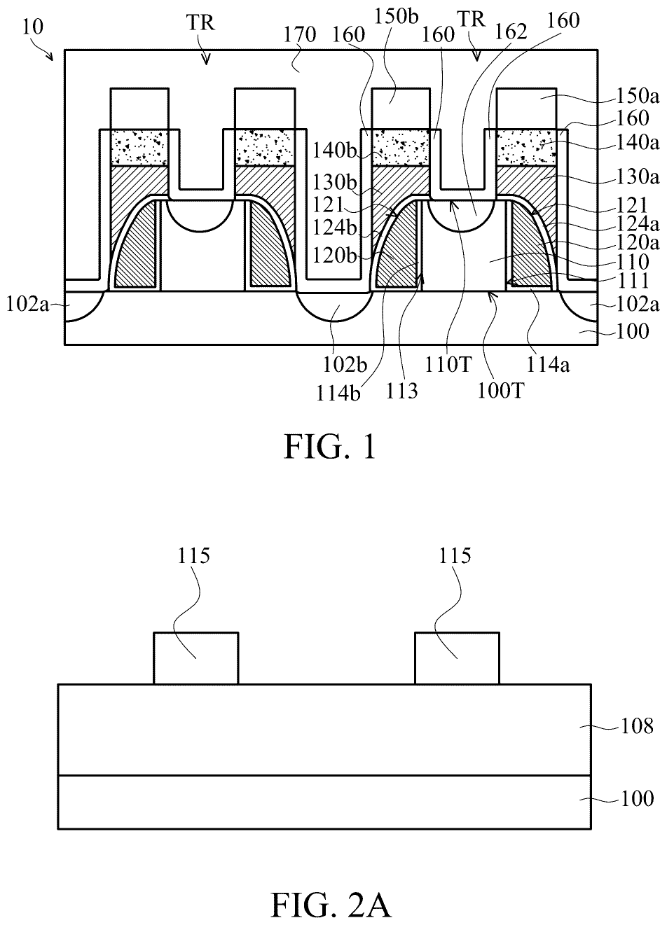

FIG. 1 is a cross-sectional view of a semiconductor memory device 10 in accordance with some embodiments. In one embodiment, the semiconductor memory device 10 includes a semiconductor substrate 100 and transistor structures. In order to simplify the diagram, herein only two adjacent transistor structures TR are depicted. The semiconductor substrate 100 has an active region (under the transistor structure TR) defined by an isolation region (not shown). The semiconductor substrate 100 may be a silicon semiconductor substrate, a semiconductor-on-insulator (SOT) substrate, or another suitable semiconductor substrate (e.g., a gallium arsenide semiconductor substrate, a gallium nitride semiconductor substrate, or a germanium silicide semiconductor substrate). In one embodiment, the semiconductor substrate 100 is a silicon semiconductor substrate. In one embodiment, the semiconductor substrate 100 has a first doping concentration with the first conductivity type (e.g., P-type).

As shown in FIG. 1, each of the transistor structures TR are disposed on the semiconductor substrate 100 and includes at least: a semiconductor layer 110, a pair of tunnel oxide layers, a pair of floating gates, and a pair of inter-gate dielectric layers, a pair of control gates, and source/drain regions. In one embodiment, the material of the semiconductor layer 110 may be the same as or similar to the semiconductor substrate 100. For example, the semiconductor layer 110 is a silicon semiconductor layer. Furthermore, the semiconductor layer 110 has a conductivity type that is the same as the conductivity type (for example, P type) of the semiconductor substrate 100, and has a second doping concentration that is different than the first doping concentration. In one embodiment, the second doping concentration is higher than the first doping concentration. In other embodiments, the second doping concentration is lower than the first doping concentration.

In one embodiment, the pair of tunnel oxide layers (including a tunnel oxide layer 114a and a tunnel oxide layer 114b) conformably cover the upper surface 100T of the semiconductor substrate 100 and two opposite sidewalls of the semiconductor layer 110. For example, the tunnel oxide layer 114a conformally covers the upper surface 100T of the semiconductor substrate 100 and the first sidewall 111 of the semiconductor layer 110, while the tunnel oxide layer 114b conformally covers the upper surface 100T of the semiconductor substrate 100 and the second sidewall 113 of the semiconductor layer 110.

In one embodiment, the pair of floating gates (including a floating gate 120a and a floating gate 120b) is disposed on the semiconductor substrate 100 and covers the first sidewall 111 and the second sidewall 113 of the semiconductor layer 110, respectively. As shown in FIG. 1, the tunnel oxide layers 114a and 114b are formed between the floating gates 120a, 120b and the semiconductor substrate 100, and between the floating gates 120a, 120b and the semiconductor layer 110. As a result, the semiconductor layer 110 can provide a channel region in the vertical direction for each of the floating gates 120a, 120b, and the semiconductor substrate 100 can provide another channel region in the horizontal direction for each of the floating gates 120a, 120b.

In particular, dual channel regions with different doping concentrations can help the semiconductor memory device 10 to perform different operations (e.g., write and erase operations) in different channel regions. This is beneficial to postpone the degradation of the tunnel oxide layers, thereby increasing the number of write and erase operations of the semiconductor memory device 10. Depending on the level of doping concentration in these channel regions, the channel region with relatively high doping concentration can be used for writing operations, and the channel region with relatively low doping concentration can be used for erasing operations.

In one embodiment, since the floating gate 120a and the floating gate 120b are disposed on the first sidewall 111 and the second sidewall 113 of the semiconductor layer 110, respectively, they can also be referred to spacer-type floating gates. The spacer-type floating gate may have an outwardly convex curved sidewall opposite to the corresponding sidewall of the semiconductor layer 110. As shown in FIG. 1, the curved sidewall 121 of the floating gate 120a is opposite to the first sidewall 111 of the semiconductor layer 110, and the curved sidewall 121 of the floating gate 120b is opposite to the second sidewall 113 of the semiconductor layer 110. Compared with the rectangular floating gate that is vertically stacked below the control gate in conventional semiconductor memory devices, the curved sidewalls can increase the upper surface area of the floating gate. This is beneficial to increase the coupling rate between the control gate and the floating gate. In one embodiment, the floating gate 120a and the floating gate 120b include polysilicon. In addition, compared with the dielectric layer disposed between adjacent floating gates in the conventional semiconductor memory device, the semiconductor layer 110 in the semiconductor memory device 10 is disposed between the floating gate 120a and the floating gate 120b. It is avoided that the floating gate 120a and the floating gate 120b are coupled to cause undesired interference (disturbance).

In one embodiment, the pair of inter-gate dielectric layers (including an inter-gate dielectric layer 124a and an inter-gate dielectric layer 124b) respectively and conformably covers the curved sidewalls 121 of the pair of floating gates 120. For example, the inter-gate dielectric layer 124a conformally covers the curved sidewall 121 of the floating gate 120a, and the inter-gate dielectric layer 124b conformally covers the curved sidewall 121 of the floating gate 120b. In one embodiment, the inter-gate dielectric layer 124a and the inter-gate dielectric layer 124b include a single layer or a multi-layer structure. For example, the inter-gate dielectric layer 124a and the inter-gate dielectric layer 124b may be a multi-layer structure that includes a silicon oxide layer/silicon nitride layer/silicon oxide layer (i.e., oxide-nitride-oxide, ONO).

In one embodiment, the pair of control gates (including the control gate 130a and the control gate 130b) is respectively disposed above the floating gate 120a and the floating gate 120b, and respectively covers the inter-gate dielectric layer 124a and inter-gate dielectric layer 124b. As a result, the inter-gate dielectric layer is located between the floating gate and the control gate. In one embodiment, the control gate 130a and the control gate 130b include polysilicon.

In one embodiment, the source/drain regions are formed in the semiconductor substrate 100 or the semiconductor layer 110 and have a second conductivity type (e.g., N-type) that is different than the first conductivity type. For example, the first source/drain region 102a and the third source/drain region 102b are formed in the semiconductor substrate 100. The first source/drain region 102a is adjacent to the curved sidewall 121 of the floating gate 120a, and the third source/drain region 102b is adjacent to the curved sidewall 121 of the floating gate 120b. On the other hand, the second source/drain region 162 is formed in the semiconductor layer 110 and between the floating gate 120a and the floating gate 120b. The second source/drain region 162 serves as a common source/drain region and is formed on a different plane from the first source/drain region 102a and the third source/drain region 102b, thus reducing the adverse effect on the channel length while changing the size of the semiconductor memory device 10.

In one embodiment, each of the transistor structures TR further includes: a pair of conductive capping layers, a pair of insulating capping layers, and a sidewall protection structure 160. In one embodiment, the pair of conductive capping layers is disposed on the control gate 130a and the control gate 130b, respectively. In one embodiment, a conductive capping layer 140a and a conductive capping layer 140b are employed to reduce the contact resistance between the control gates 130a and 130b and the overlying gate contacts (not shown). In one embodiment, the conductive capping layer 140a and the conductive capping layer 140b include metal, metal silicide, or other suitable conductive materials. For example, the conductive capping layer 140a and the conductive capping layer 140b include tungsten or tungsten silicide.

In one embodiment, the pair of insulating capping layers (including the insulating capping layer 150a and the insulating capping layer 150b) is disposed on the conductive capping layer 140a and the conductive capping layer 140b, respectively. In one embodiment, the insulating capping layers 150a and 150b are used as hard masks to protect and define the underlying layers, such as the conductive capping layers and control gates, during fabrication of the transistor structure TR. In one embodiment, the insulating capping layer 150a and the insulating capping layer 150b include nitride, oxynitride or other suitable dielectric materials.

In one embodiment, the sidewall protection structure 160 is disposed on the two opposite sidewalls of the control gate 130a and the conductive capping layer 140a and on the two opposite sidewalls of the control gate 130b and the conductive capping layer 140b, and extends on the upper surface 100T of the semiconductor substrate 100 and the upper surface 110T of the semiconductor layer 110 to cover the first source/drain region 102a, the second source/drain region 162 and the third source/drain region 102b, such as shown in FIG. 1.

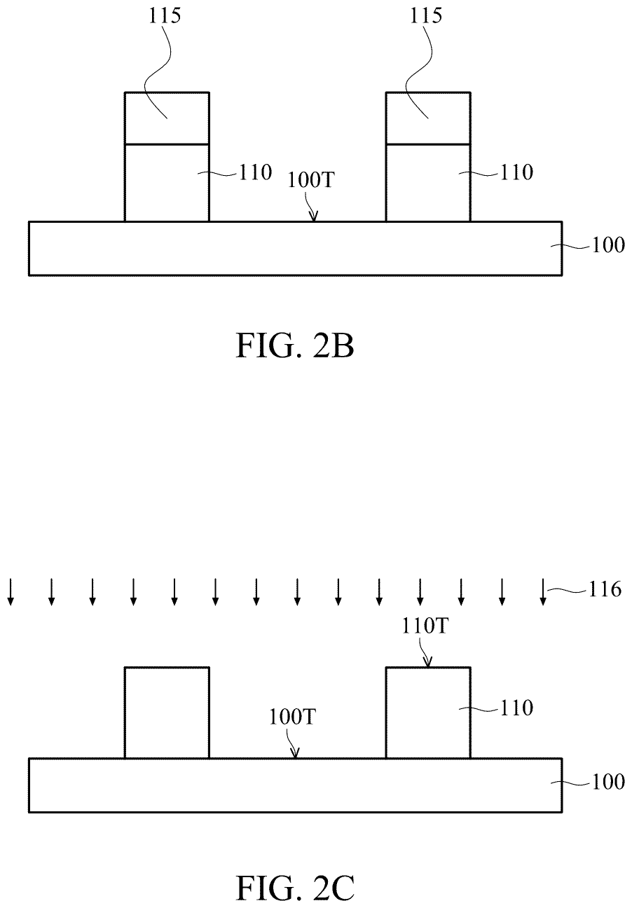

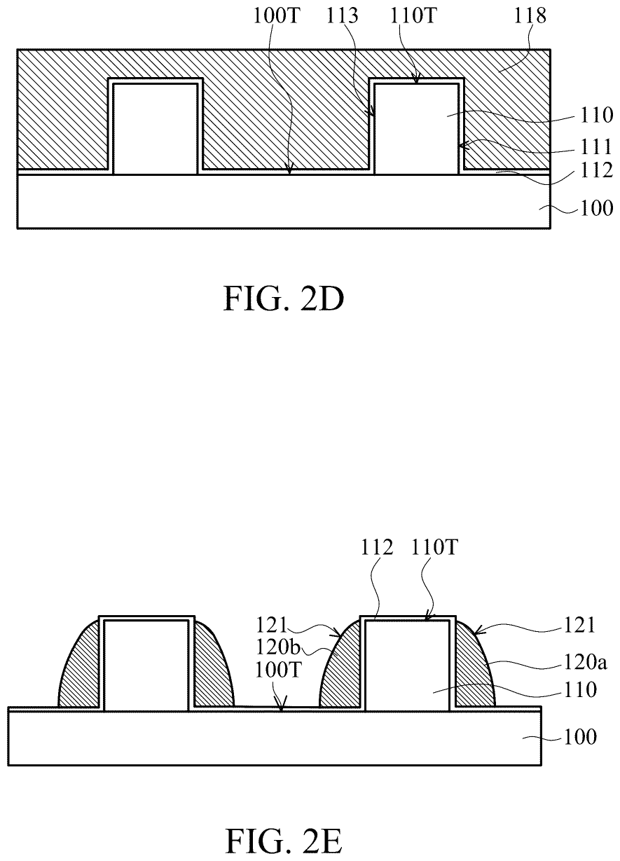

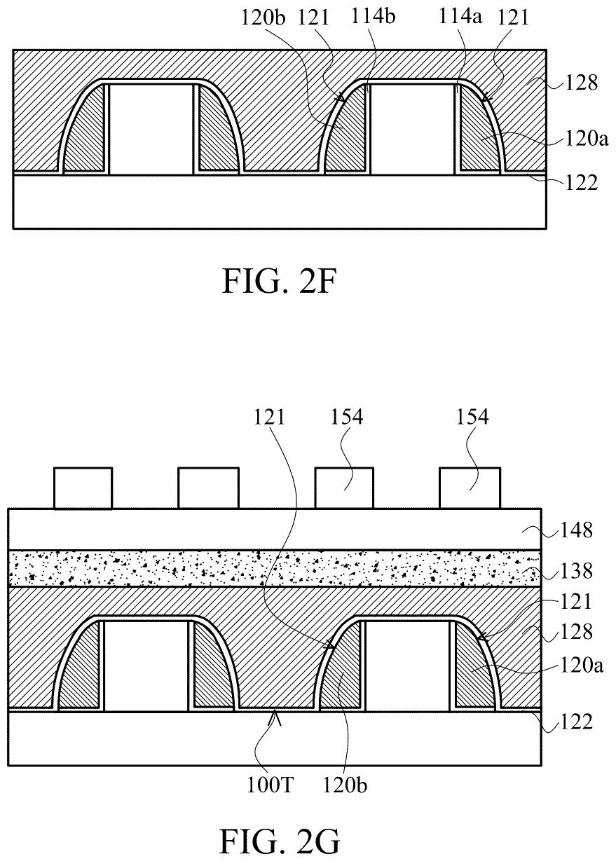

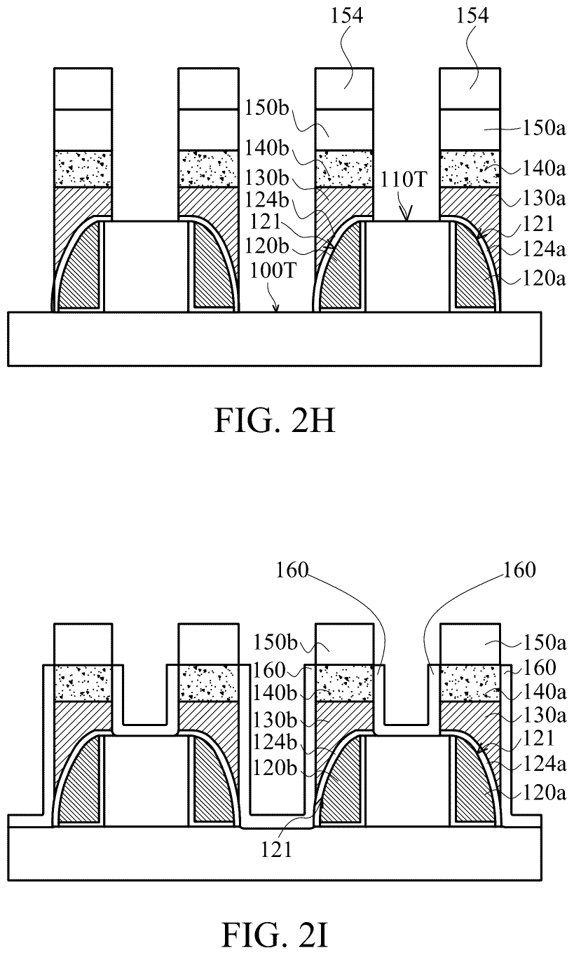

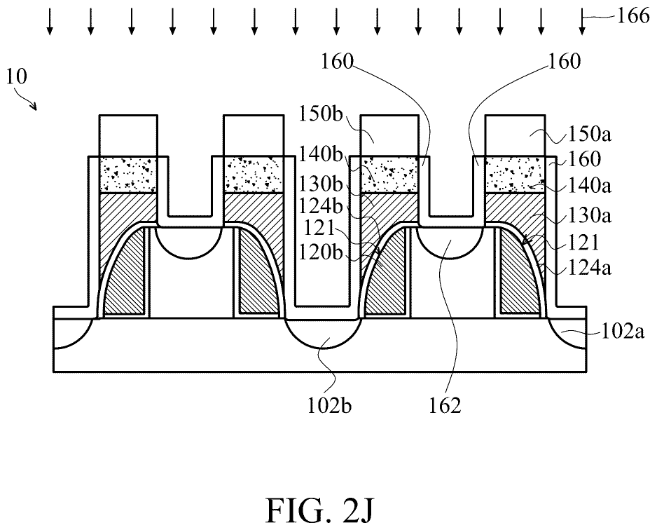

FIGS. 2A to 2J are cross-sectional views of semiconductor memory devices at various stages of processing in accordance with some embodiments. Elements in FIGS. 2A to 2J that are the same as those in FIG. 1 are labeled with the same reference numbers as in FIG. 1 and may not be described again for brevity. Referring to FIG. 2A, in one embodiment, a semiconductor substrate 100 is provided and another semiconductor substrate 108 is formed on the semiconductor substrate 100. In one embodiment, the semiconductor substrates 100 and 108 are silicon semiconductor substrates and have the same or similar materials and the same conductivity type (e.g., P-type). Furthermore, the semiconductor substrate 100 has a first doping concentration and the semiconductor substrate 108 has a second doping concentration different than the first doping concentration. In one embodiment, the second doping concentration is greater than the first doping concentration. In other embodiments, the second doping concentration is less than the first doping concentration.

Next, a photolithography process is performed to form a photoresist pattern on the semiconductor substrate 108. In one embodiment, the photoresist pattern has parallel-arranged strip patterns 115 for patterning the semiconductor substrate 108 in subsequent processes to form semiconductor layers of an active region. Herein, in order to simplify the diagram, only two strip patterns 115 are depicted, as shown in FIG. 2A.

Refer to FIG. 2B. In one embodiment, an etching process (for example, a dry or wet etching process) is performed using the strip patterns 115 as etching mask, so as to form semiconductor layers 110 on the upper surface of 100T of the semiconductor substrate 100. Afterwards, referred to FIG. 2C, after removing the strip patterns 115 to expose the upper surface 110T of the semiconductor layer 110, an optional channel doping process 116 may be performed on the semiconductor substrate 100 and the semiconductor layer 110. For example, a first conductivity type (for example, P-type) ion implantation process is performed on the semiconductor substrate 100 and the semiconductor layer 110.

Refer to FIG. 2D, in one embodiment, a dielectric layer 112 is conformally formed by using chemical vapor deposition, atomic layer deposition or other suitable deposition processes, to cover the upper surface 100T of the semiconductor substrate 100 and the upper surface 110T of the semiconductor the layer 110 and the opposite first sidewalls 111 and second sidewalls 113. In one embodiment, the dielectric layer 112 serves as a tunnel dielectric layer and includes a single layer or a multi-layer structure. For example, the dielectric layer 112 has a single layer structure and includes silicon oxide. Next, in one embodiment, a conductive layer 118 is formed on the dielectric layer 112 above the semiconductor layer 110 and fills the space between adjacent semiconductor layers 110 by using chemical vapor deposition or other suitable deposition processes, to cover the dielectric layer 112 formed on the first sidewalls 111 and the second sidewalls 113 of the semiconductor layers 110. In one embodiment, the conductive layer 118 includes polysilicon.

Refer to FIG. 2E, floating gates (e.g., floating gates 120a and 120b) are formed on the dielectric layer 112 on the semiconductor substrate 100. The floating gate 120a and the floating gate 120b respectively cover the dielectric layer 112 on the first sidewall 111 and the second sidewall 113 of the semiconductor layer 110. In one embodiment, an anisotropic etching process is performed to expose the dielectric layer 112 formed on the upper surface 100T of the semiconductor substrate 100 and the dielectric layer 112 formed on the upper surface 110T of the semiconductor layer 110. The remaining conductive layer 118 forms a spacer-type floating gate 120a and a spacer-type floating gate 120b on the first sidewall 111 and the second sidewall 113 of each semiconductor layer 110, respectively. In one embodiment, each of the floating gate 120a and the floating gate 120b has a curved sidewall 121. Furthermore, the floating gate 120a is opposite to the first sidewall 111 of the semiconductor layer 110, and the floating gate 120b is opposite to the second sidewall 113 of the semiconductor layer 110.

Refer to FIG. 2F, in one embodiment, a patterning process (e.g., photolithography and etching processes) is performed on the semiconductor substrate 100 to form isolation trenches (not shown) in the semiconductor substrate 100 and the active region (which is below the transistor structure TR) defined by the isolation trenches. Afterwards, an dielectric material is filled into the isolation trenches, and then a chemical mechanical polishing process and a recessing process are performed on the dielectric material to form isolation regions (not shown) in the semiconductor substrate 100. During the chemical mechanical polishing process, the dielectric layer 112 on the upper surface 110T of the semiconductor layer 110 is removed. During the recessing process, the portion of the dielectric layer 112 on the upper surface 100T of the semiconductor substrate 100 is removed (the portion of the dielectric layer that is exposed from the floating gate 120a and the floating gate 120b). As a result, a tunnel oxide layer 114a is formed between the floating gate 120a and the semiconductor substrate 100 and between the floating gate 120a and the semiconductor layer 110. Furthermore, a tunnel oxide layer 114b is formed between the floating gate 120b and the semiconductor substrate 100 and between the floating gate 120b and the semiconductor layer 110.

Refer to FIG. 2F again, in one embodiment, after forming the isolation region, a dielectric layer 122 is formed by chemical vapor deposition, atomic layer deposition or other suitable deposition processes, to cover the upper surface 100T of the semiconductor substrate 100, the upper surface 110T of each semiconductor layer 110, and the curved sidewall 121 of each of the floating gates 120a and 120b. In one embodiment, the dielectric layer 122 serves as an inter-gate dielectric layer and includes a single layer or a multi-layer structure. For example, the dielectric layer 122 may be a multi-layer structure including a silicon oxide layer/silicon nitride layer/silicon oxide layer (oxide-nitride-oxide, ONO). Herein, in order to simplify the diagram, a single layer is depicted as the dielectric layer 122.

Next, in one embodiment, a conductive layer 128 is formed on the inter-gate dielectric layer 122 on the semiconductor layer 110 and fills the spaces between the adjacent semiconductor layers 110 by using chemical vapor deposition or other suitable deposition processes, to cover the dielectric layer 122 on the curved sidewall 121 of each of the floating gates 120a and 120b. In one embodiment, the conductive layer 128 includes polysilicon.

Refer to FIG. 2G, in one embodiment, a conductive layer 138 and an insulating layer 148 are successively formed on the conductive layer 128 by using chemical vapor deposition or other suitable deposition processes. Afterwards, a photolithography process is performed to form a photoresist pattern on the insulating layer 148. In one embodiment, the photoresist pattern has parallel-arranged strip patterns 154 for successively patterning the insulating layer 148, the conductive layer 138, the conductive layer 128, and the dielectric layer 122 in subsequent processes. In one embodiment, the conductive layer 138 includes metal or metal silicide or other suitable conductive material. For example, the conductive layer 138 includes tungsten or tungsten silicide. In one embodiment, the insulating layer 148 includes silicon nitride, silicon oxynitride, or other suitable dielectric materials.

Refer to FIG. 2H, in one embodiment, an etching process (for example, a dry or wet etching process) is performed by using the strip patterns 115 as an etching mask, to successively form the inter-gate dielectric layer 124a, the control gate 130a, the conductive capping layer 140a and the insulating capping layer 150a on the floating gate 120a, and successively form the inter-gate dielectric layer 124b, the control gate 130b and the conductive capping layer 140b, and the insulating capping layer 150b on the floating gate 120b.

Refer to FIG. 2I, in one embodiment, a sidewall protection structure 160 is conformally formed on the two opposite sidewalls of the conductive capping layer 140a and the control gate 130a, and on the two opposite sidewalls of the conductive capping layer 140b and the control gate 130b, and extends to the upper surface 100T of the semiconductor substrate 100 and the upper surface 110T of the semiconductor layer 110. In one embodiment, the sidewall protection structure 160 includes silicon oxide and is formed by a thermal oxidation process.

Refer to FIG. 2J, in one embodiment, a second conductivity type (e.g., N-type) doping process 166 is performed to form a first source/drain region 102a in the semiconductor substrate 100 adjacent to the floating gate 120a, a second source/drain region 162 in the semiconductor layer 110 between the floating gate 120a and the floating gate 120b, and a third source/drain region 102b in the semiconductor substrate 100 adjacent to the floating gate 120b. As a result, the fabrication of the semiconductor recording device 10 can be completed.

In one embodiment, after forming the first source/drain region 102a, the second source/drain region 162 and the third source/drain region 102b, a dielectric layer 170 (sometimes also called an interlayer dielectric layer) is further formed on each transistor structure TR and fills the space between adjacent transistor structures TR, as shown in FIG. 1.

According to the foregoing embodiments, each transistor structure in the semiconductor memory device of the present disclosure has a pair of spacer-type floating gates, and the floating gates have curved sidewalls. In such a configuration, the coupling rate between the floating gate and the overlying control gate can be improved by increasing the contact area between the curved sidewall of the floating gate and the control gate. According to the foregoing embodiments, the floating gates of each transistor structure in the semiconductor memory device have channel regions with different doping concentrations in the horizontal and vertical directions, which can be used for write and erase operations in the memory device, respectively, thereby effectively improving the operating endurance (i.e., increasing the number of write operations and erase operations) of the tunnel oxide layer between the floating gate and the channel region. According to the foregoing embodiments, the spacer-type floating gates in the semiconductor memory device are separated from each other by a semiconductor layer, so that the undesired interference between the floating gates can be avoided. According to the foregoing embodiments, the source region and the drain region on both sides of each floating gate in the semiconductor memory device are not on the same plane, so that the adverse impact on the channel length while changing the size of the semiconductor memory device 10 can be reduced.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor memory device, comprising:
a semiconductor substrate having a first doping concentration with a first conductivity type; and
a plurality of transistor structures disposed on the semiconductor substrate, each of the transistor structures comprising:
a semiconductor layer having a second doping concentration with the first conductivity type, wherein the second doping concentration is different than the first doping concentration;
a first floating gate covering a first sidewall of the semiconductor layer and having a curved sidewall opposite to the first sidewall;
a first tunnel oxide layer formed between the first floating gate and the semiconductor substrate, and between the first floating gate and the semiconductor layer;
a first control gate disposed on the first floating gate; and
an inter-gate dielectric layer formed between the first control gate and the first floating gate and conformably covering the curved sidewall of the first floating gate.

2. The semiconductor memory device as claimed in claim 1, wherein each of the transistor structures further comprises:
a first source/drain region and a second source/drain region formed in the semiconductor substrate and the semiconductor layer, respectively, and having a second conductivity type different than the first conductivity type, wherein the first source/drain region is formed adjacent to the curved sidewall of the first floating gate, and the second source/drain region is formed between the first floating gate and the second floating gate.

3. The semiconductor memory device as claimed in claim 1, wherein the first conductivity type is P-type, and the second conductivity type is N-type.

4. The semiconductor memory device as claimed in claim 3, wherein the second doping concentration is greater than the first doping concentration.

5. The semiconductor memory device as claimed in claim 3, wherein the second doping concentration is less than the first doping concentration.

6. The semiconductor memory device as claimed in claim 1, wherein each of the transistor structures further comprises:
a first conductive capping layer disposed on the first control gate; and
a first insulating capping layer disposed on the first conductive capping layer.

7. The semiconductor memory device as claimed in claim 6, wherein the first control gate comprises polysilicon, and the first conductive capping layer comprises metal or metal silicide.

8. The semiconductor memory device as claimed in claim 1, wherein each of the transistor structures further comprises:
a second floating gate covering a second sidewall of the semiconductor layer opposite to the first sidewall, and having a curved sidewall opposite to the second sidewall;
a second control gate disposed on the second floating gate, wherein the inter-gate dielectric layer is formed between the second control gate and the second floating gate and conformally covers the curved sidewall of the second floating gate; and
a second tunnel oxide layer formed between the second floating gate and the semiconductor substrate and between the second floating gate and the semiconductor layer.

9. The semiconductor memory device as claimed in claim 8, wherein each of the transistor structures further comprises:
a third source/drain region formed in the semiconductor substrate and having a second conductivity type different than the first conductivity type, wherein the third source/drain region is formed adjacent to the curved sidewall of the second floating gate.

10. The semiconductor memory device as claimed in claim 8, wherein each of the transistor structures further comprises:
a sidewall protection structure formed on two opposite sidewalls of the first control gate and two opposite sidewalls of the second control gate, and extends to upper surfaces of the semiconductor substrate and the semiconductor layer.

11. The semiconductor memory device as claimed in claim 8, wherein each of the transistor structures further comprises:
a second conductive capping layer disposed on the second control gate; and
a second insulating capping layer disposed on the second conductive capping layer.

12. A method for forming a semiconductor memory device, comprising:
forming at least one semiconductor layer on a semiconductor substrate, wherein the semiconductor substrate has a first P-type doping concentration and the semiconductor layer has a second P-type doping concentration, and the second P-type doping concentration is different than the first P-type doping concentration;
conformally forming a first dielectric layer to cover an upper surface of the semiconductor substrate and cover an upper surface, a first sidewall and an opposing second sidewall of the semiconductor layer;
forming a first floating gate and a second floating gate on the first dielectric layer and covering the first sidewall and the second sidewall, respectively, wherein the first floating gate has a curved sidewall opposite to the first sidewall and the second floating gate has a curved sidewall opposite to the second sidewall;
conformally forming a second dielectric layer to cover the upper surface of the semiconductor substrate, the upper surface of the semiconductor layer, the curved sidewall of the first floating gate and the curved sidewall of the second floating gate; and
forming a first control gate to cover the second dielectric layer on the first floating gate and forming a second control gate to cover the second dielectric layer on the second floating gate.

13. The method as claimed in claim 12, further comprising:
successively forming a conductive capping layer and an insulating capping layer on the first control gate and on the second control gate prior to the formation of the first control gate and the second control gate; and
forming a sidewall protection structure on two opposite sidewalls of the first control gate and two opposite sidewalls of the second control gate, and extending to the upper surfaces of the semiconductor substrate and the semiconductor layer.

14. The method as claimed in claim 13, further comprising:
performing an N-type doping process to form a first source/drain region in the semiconductor substrate adjacent to the first floating gate, a second source/drain region in the semiconductor layer between the first floating gate and the second floating gate, and a third source/drain region in the semiconductor substrate adjacent to the second floating gate.

15. The method as claimed in claim 12, further comprising:
removing the first dielectric layer on the upper surface of the semiconductor substrate, on the upper surface of the semiconductor layer, and exposed from the first floating gate and the second floating gate prior to the formation of the second dielectric layer.
